(19) United States
(12) Patent Application Publication
(10) Pub. No.: US 2009/0206963 A1
(43) Pub. Date: Aug. 20, 2009

(54) TUNABLE METAMATERIALS USING MICROELECTROMECHANICAL STRUCTURES

(75) Inventors: Vinh N. Nguyen, Durham, NC (US); Serdar H. Yonak, Ann Arbor, MI (US); David R. Smith, Durham, NC (US); Jungsang Kim, Chapel Hill, NC (US)

Correspondence Address: GIFFORD, KRASS, SPRINKLE,;ANDERSON & CITKOWSKI, P.C., P.O. BOX 7021, TROY, MI, 48007-7021, US

(73) Assignees: Toyota Motor Engineering & Manufacturing North America, Inc., Erlanger, KY (US); Duke University, Durham, NC (US)

(21) Appl. No.: 12/032,069

(22) Filed: Feb. 15, 2008

(51) Int. Cl. H03H 9/24

(52) U.S. Cl. 334/14

(57) ABSTRACT

A metamaterial comprises a support medium, such as a planar dielectric substrate and a plurality of resonant circuits supported thereby. At least one resonant circuit is a tunable resonant circuit including a conducting pattern and a voltage-tunable capacitor, so that an electromagnetic parameter (such as resonance frequency) may be adjusted using an electrical control signal. In some examples of the present invention, the voltage-tunable capacitor includes a MEMS structure.

### FIELD OF THE INVENTION

The invention relates to metamaterials, in particular to metamaterials having tunable properties.

### BACKGROUND OF THE INVENTION

Metamaterials are typically composites having an artificial structure. The structure may be designed to obtain desirable electromagnetic properties such as permittivity and permeability at a desired operating frequency.

Example metamaterials have a repeated unit cell, each unit cell including an electrically conducting pattern. The electrically conducting pattern may be supported by a dielectric substrate. The dimensions of the unit cell are usually chosen to be smaller than the wavelength of the electromagnetic radiation at the operating frequency. Metamaterials are particularly useful for radar wavelengths as the pattern conductor may be fabricated using conventional printed circuit board techniques or semiconductor manufacturing techniques.

The metamaterial properties are related by parameters of component unit cells. Manufacturing variations can be introduced into the unit cells to obtain varying properties, sometimes within the same metamaterial. However, it would be very useful to adjust the electromagnetic properties of a metamaterial after fabrication.

### SUMMARY OF THE INVENTION

Examples of the present invention include a metamaterial having an electromagnetic properties that can be adjusted using an electrical control signal to modify the capacitance of one or more variable capacitors. Example metamaterials include a plurality of unit cells, at least one unit cell (and typically many) including a tunable element, such as a variable capacitor having a voltage-controllable MEMS (microelectromechanical system) element, such as a capacitor having at least one electrode that can be deformed using an electric potential.

An example metamaterial includes a plurality of unit cells, at least one unit cell having a tunable capacitive element that allows adjustment of a unit cell parameter using a control signal. For example, the capacitance of a variable capacitor may be controlled using a control voltage. Examples of the present invention include capacitors having at least one electrode that may be physically deformed using the control voltage. Electrode deformation modifies the capacitive gap between the capacitor electrodes, allowing the capacitance to be varied. Hence, the electromagnetic properties of a metamaterial including such unit cells may be adjusted using an electrical control signal.

An example variable capacitor comprises a first electrode and a second electrode, the relative separation of the first and second electrodes being controllable using a control voltage. A metamaterial according to an example of the present invention includes such a variable capacitor. In one approach, an electrical potential applied between the first and second electrodes may be used to modify the separation thereof. In other examples, an electrical potential may be applied between the first electrode and a third electrode, the third electrode being mechanically coupled to the second electrode. In further examples, an electrical potential may be applied between third and fourth electrodes, the third electrode being mechanically coupled to the first electrode and the fourth electrode being mechanically coupled to the third electrode. Other configurations will be apparent to the skilled artisan.

### BRIEF DESCRIPTION OF THE DRAWINGS

FIGS. 1A-1B show a metamaterial comprising a plurality of unit cells;

FIG. 2A shows a possible structure of a variable capacitor;

FIG. 2B shows deformation of an overlapping structure including a capacitor electrode;

FIGS. 3A-3B show a unit cell of a metamaterial including a variable capacitor;

FIGS. 4A-4B show configurations in which a capacitance gap may be adjusted;

FIG. 5 shows a further overleaf structure for a variable capacitor;

FIG. 6 shows a further configuration of a support structure;

FIGS. 7A-7D show a control system according to an embodiment of the present invention;

FIG. 8 shows a cross-section of an example variable capacitor;

FIG. 9 shows a unit cell including a variable capacitor;

FIGS. 10A-10B show simulation results for a metamaterial;

FIG. 11 shows a unit cell including two variable capacitors;

FIG. 12 shows simulation results for a metamaterial;

FIGS. 13A-13B show electron microscope images of a variable capacitor;

FIG. 14 shows electron microscope images of a variable capacitor from an oblique aspect; and

FIGS. 15A-B show optical micrographs of capacitor operation.

### DETAILED DESCRIPTION OF THE PREFERRED EMBODIMENTS

Examples of the present invention include metamaterials having an electromagnetic property, such as effective permittivity at a given operating frequency that can be adjusted using a control signal. The control signal can be an electrical signal used to adjust capacitance values within one or more unit cells of the metamaterial.

For example, a control signal voltage can be used to adjust the mechanical deflection of a capacitor electrode relative to an opposed electrode of the capacitor. A variable capacitor may include first and second electrodes, the relative separation thereof being electrically controllable. A metamaterial may thereby have an electromagnetic property that can be adjusted using the control signal. A property may be adjusted over the whole of the metamaterial. In other examples a gradient of electromagnetic property may be obtained, allowing tunable metamaterial lenses to be obtained.

An example metamaterial includes a plurality of unit cells, each unit cell including a resonant circuit. A resonant circuit may be formed as a conducting pattern, such as a split-ring resonator. A resonant circuit may comprise a conducting pattern formed as a film on a dielectric substrate. At least one unit cell of the metamaterial includes a variable capacitor that allows adjustment of a unit cell parameter, such as resonance frequency, using a control signal. For example, the capacitance of a variable capacitor may be controlled using a bias voltage. Examples of the present invention include capacitors in which relative electrode separation, and hence capacitance, can be modified by applying an electrical control signal. Changes in relative electrode separation may be achieved by physical deformation of at least one electrode using a mechanical force arising from the electrical potential applied between control electrodes. The mechanical force may act to urge the electrodes together, or to push them apart, and a change in relative separation is correlated with the magnitude and sign of relative electrical potential, elastic properties of deformable elements, and may possibly be limited by mechanical limiters.

In some examples, the control electrodes may be the same as the capacitor electrodes, or may be proximate. For example a control electrode and a capacitor electrode may both proximate, but not electrically connected, and supported by the same deformable element. Electrode deformation as a result of the control voltage modifies the capacitive gap between the capacitor electrodes, modifying the capacitance.

The term resonant circuit may refer to a conducting pattern having inductive and capacitive properties, such as a split-ring resonator. The term resonant circuit includes circuits in which the resonant frequency may be high enough to be unachievable due to frequency dependence of component properties. Metamaterial properties such as index, permittivity, permeability, and the like are frequency dependent, and can be modeled in terms of resonant circuit properties. Hence, at a particular operating frequency, metamaterial properties may be modeled in terms of resonant circuits having a resonant frequency much higher than the operating frequency. Metamaterials may be negative index materials close to a resonance, which can be useful for some applications. In some cases, operation may be close to resonance (e.g. if negative index materials are desired). However, in some examples of the present invention operation near the resonance may be avoided because of associated losses, operating frequencies chosen above or below resonance, and the metamaterials used as positive index materials.

A metamaterial may comprise a plurality of unit cells. For example, each unit cell may include an electrically conducting pattern supported on a dielectric substrate. In other examples, the electrically conducting pattern may be self-supporting, or other forms of substrate may be used. The electrically conducting pattern may be a resonant circuit, having parameters such as a resonance frequency. Electromagnetic properties of the metamaterial are related to the operating frequency of metamaterial relative to the resonance frequency of various component resonant circuits. In some examples, each unit cell includes a resonant circuit, the resonant circuit comprising a conducting pattern and a variable capacitor.

In some modes of metamaterial operation, the operating frequency may be relatively close to the resonance frequency of component unit cells. An operating frequency close to resonance allows a suitably configured metamaterial to act as a negative material at the operating frequency, having negative permittivity and/or negative permeability. It has been previously determined that lens properties using such negative materials may have less aberration than lenses formed from conventional positive materials. However, a disadvantage of operating close to resonance frequencies is that resistive losses are increased. Hence, it may be preferable to operate at frequencies sufficiently away from the resonance frequency to avoid substantial losses. For example, the resonance frequency of component unit cells may be above 100 megahertz, with operation at frequencies below 100 megahertz. In other examples, operating frequencies may be above 1 gigahertz, with resonant frequencies below 100 megahertz. Operation may be at frequencies above or below the resonance frequency.

A metamaterial may have substantially uniform properties over its spatial extent, for example comprising a plurality of resonant circuits, each having a similar resonance frequency. In other examples, metamaterial properties may have a spatial variation. For example, the index may vary in one or more directions. This variation may be achieved by spatial variation of resonant frequencies, and in examples of the present invention this may be achieved using a control signal.

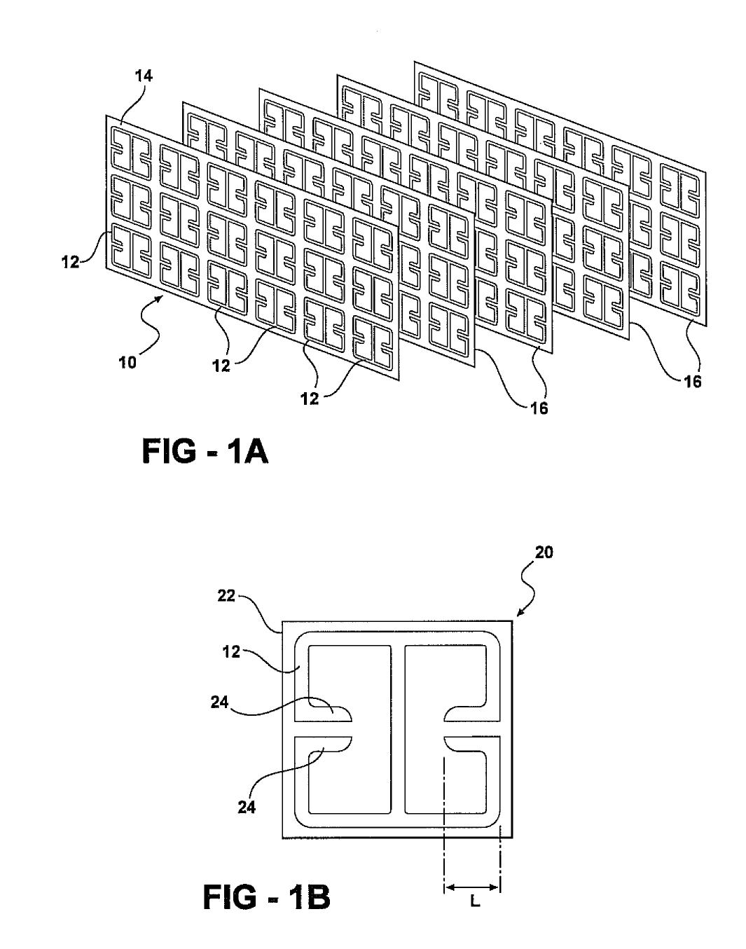

FIG. 1A illustrates a conventional metamaterial 10, comprising at least one substrate 14 on which a plurality of conducting patterns 12 are disposed. In this example, a plurality of substrates are used, the additional substrates 16 being generally parallel to substrate 14 and spaced apart. In this figure, the spacing is exaggerated for illustrative clarity.

FIG. 1B shows a conventional unit cell including a resonator, in this case an electrically-coupled resistor-inductor (ELC) resonator in the form of a conducting pattern which may be used in a metamaterial. The unit cell shown generally at 20 includes conducting pattern 12, having the same form as shown in FIG. 1A. A capacitive gap is formed by capacitive pads 14 having a pad length. In this example, the pad length has the same value for both capacitive gaps. The periphery of the unit cell 22 need not correspond to any physical structure, the dimensions being related to the pattern repeat on the substrate surface. In this example, the pad length is a feature length L, variation of which allows index to be varied.

A conventional metamaterial includes a repeating pattern having constant values of pad lengths. The properties of the metamaterial are related to parameters of the unit cell, such as the pad length. The unit cell of a metamaterial includes a conducting pattern, in this example a split ring resonator configuration having inductive and capacitive components. As shown, the index of a metamaterial is a function of the capacitive component. One approach is to vary the capacitive pad length, but this approach is limited by the physical limits to size variation.

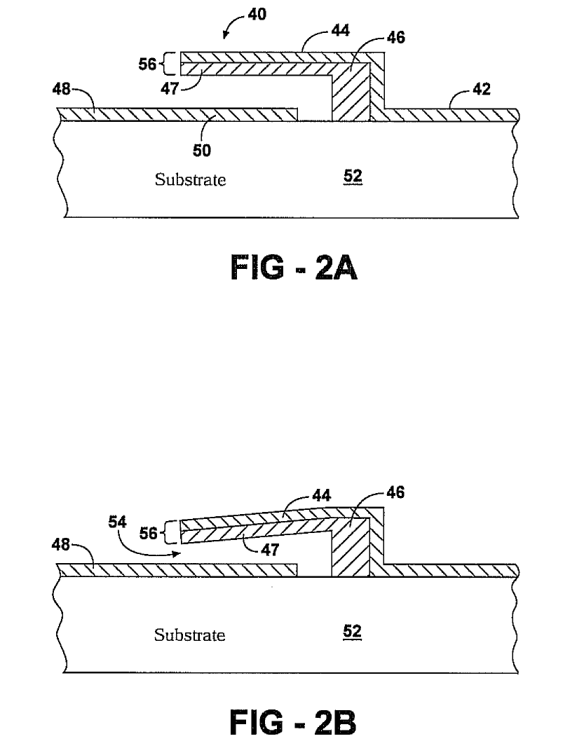

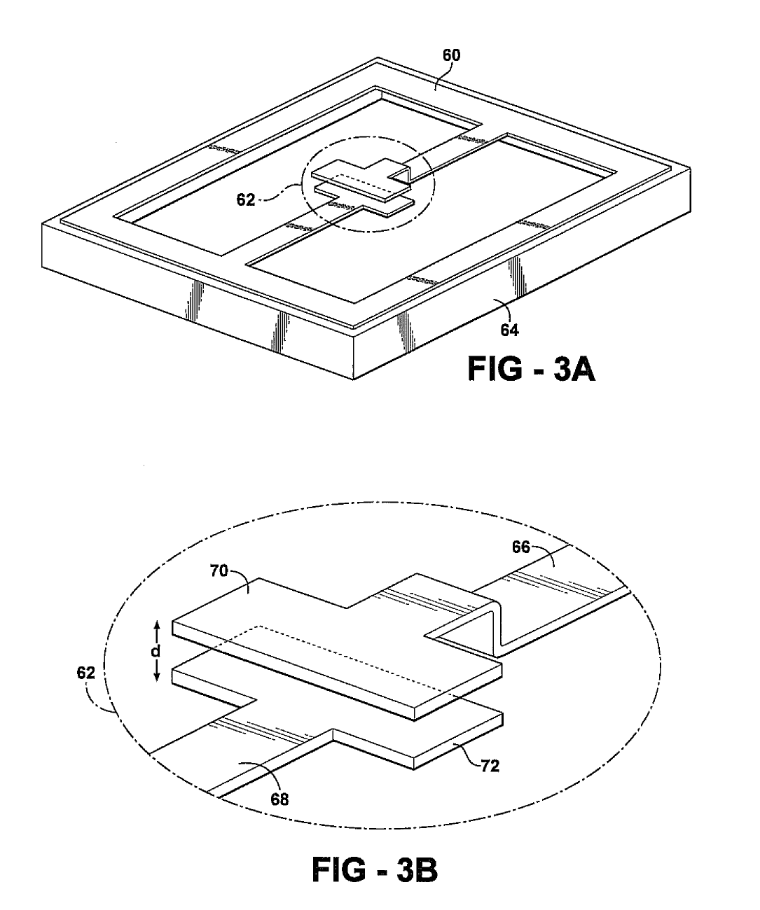

FIG. 2A shows an example structure for a variable capacitor 40, comprising a metal film that extends from conducting segment 42 over into a deformable structure 56, and provides first electrode 44. A second metal film 48 provides a second electrode 50, proximate to the first electrode. A capacitive gap exists between first and second electrodes. The metal films 42 and 48 are deposited on substrate 52, and the first film extends into electrode 44 as part of overleaf structure 56. In representative examples, overleaf structure 56 includes a polysilicon MEMS structure including deformable region 47 and support region 46.

The capacitive gap between first and second electrodes can be adjusted by modifying the relative separation of first and second electrodes. This may be achieved using a control voltage.

FIG. 2B is similar to FIG. 2A, and shows the deformable structure 56, comprising first electrode and deformable MEMS region, deflected towards the second electrode through the application of a bias voltage between first and second electrodes. This provides a smaller capacitive gap 54, increasing the capacitance. The bias voltage may be applied as a control signal, and may vary with time so as to provide a dynamically tunable capacitance.

Conducting films may comprise any conducting material, such as metals and conducting polymers. The MEMS structure may be fabricated using any appropriate technique, from any suitable material. The use of polysilicon is representative and not limiting. The substrate 52 may be a dielectric substrate, such as a polymer sheet, insulating silicon, insulating oxide (such as sapphire), or glass layer. However other substrate materials may be used, and in some examples conducting layers may be in part self-supporting. The substrate may be a multilayer structure, and may in some examples include conducting sub-layers.

The effect of applying the electrical potential across the capacitive gap deforms the overlapping structure 56 towards the substrate and the second electrode, increasing the capacitance. This configuration allows an excellent range of capacitances to be achieved. The ratio of minimum capacitance to maximum capacitance may exceed a factor of two, and in some examples may exceed a ratio of five. Furthermore, unlike semiconductor devices, the relative direction of applied electric potential may not be greatly significant.

FIG. 3A shows a unit cell of a metamaterial, comprising a conductive pattern 60 disposed on substrate 64 in the general form of an electrically-coupled resistor-inductor (ELC) resonator. The structure includes overleaf capacitor, shown generally at 62.

FIG. 3B shows slightly more detail of the capacitor. The overleaf capacitor 62 is formed by extensions of electrically conducting segments 66 and 68, and comprises a first electrode 70 that in part overlaps second electrode 72 within an overlap region. The capacitive gap between first and second electrodes is correlated with distance d, and this may be adjusted using relative electrical potentials applied to first and second electrodes. For example, if the electric potential applied to the first electrode is of opposite polarity to that applied to the second electrode an attractive electrostatic force will tend to reduce the capacitive gap and increase the capacitance. Similarly, the gap may in some examples be increased through application of a similar sign potential to first and second electrodes.

In this example, both electrodes are generally within the plane of the substrate 64, the second electrode being supported by substrate surface and the first electrode being generally parallel to the first electrode and slightly offset in a direction orthogonal to the substrate surface. As discussed further elsewhere, the first electrode may be supported by a deformable electrically insulating structure.

Other configurations are possible, including those in which capacitance electrodes exist generally in a plane perpendicular to the substrate. In some examples, the electrodes may have a curvature, the distance between substantially parallel and curved electrodes being adjustable using a variable bias voltage.

In the example shown in FIG. 3A a potential applied across the center gap of the split ring resonator allows active parameter control by changing the relative electrode separation and hence capacitance. A potential may be induced between the electrodes even though they are otherwise interconnected by the portions of resonator structure 60. Substantial impedance may exist at radio frequencies, or other operating frequencies, allowing a potential to be applied across the capacitance gap that is not effectively shorted out by the remainder of the conducting pattern. The structures illustrated in FIG. 3B and FIG. 2 may be used in any resonator configuration, and not just the resonator configuration shown in FIG. 3A.

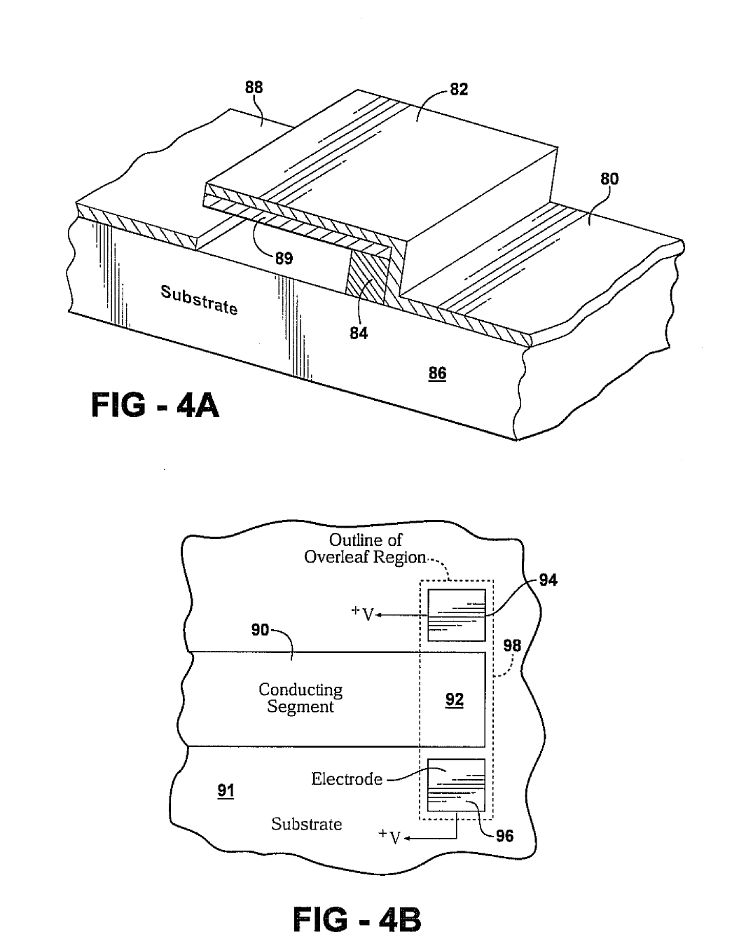

FIG. 4A shows a structure in cross-section including first conducting segment 80, extending into first electrode 82, second electrical conductor 88, substrate 86, insulating support region 84, and deformable insulating overleaf support 89. In this example, there is no significant overlap of conducting regions. However, the insulating overleaf support 89 may be deformed by electrostatic forces developed between the electrode 82 and the end portion of the electrical conductor 88, which acts as the second electrode. In other examples, the second electrical conductor 88 may extend under the overleaf support 89.

FIG. 4B shows (in part) a configuration which allows a capacitance gap to be adjusted without applying an electric potential between two portions of the same conducting pattern. In this example, a first capacitance gap electrode is formed at 92 as an end portion of conducting segment 90. The figure also shows a separate deformation control electrodes at 94 and 96. The deformation control electrodes are both supported by a substrate 91 but are not otherwise electrically interconnected to the conducting pattern that forms the resonant circuit. The dashed line 98 shows the extent of a possible overleaf structure (not shown for clarity). A second capacitive gap electrode may be formed on a portion of the overleaf structure, for example as an extension of a second conducting segment (not shown) on the substrate. A force induced by the electrical potential introduced between the overleaf deformation electrodes and the second capacitive gap electrode induces physical deformation of the overleaf structure. An electrical potential may be applied between the overleaf deformation electrodes and a capacitive gap electrode using a control signal.

Hence, the capacitive gap can be controlled by an electrical potential between a first capacitive gap electrode and one or more overleaf deformation electrode. A second capacitive gap electrode may be physically oppose the first capacitive gap electrode, in part or in whole, or be laterally offset (e.g. offset in a direction parallel to the substrate surface). A capacitive gap electrode may be extended laterally (e.g. normal to the direction of elongation of a conducting segment) so as to oppose an overleaf deformation electrode.

Hence, conductive regions (electrodes) on the substrate and overleaf structure are used to control the capacitance gap through an electrical potential applied between these opposed conductive regions. A conductive region used to control the capacitance gap is not necessarily part of the resonator pattern of the metamaterial unit cell. However such additional conducting regions may slightly modify the properties of the metamaterial. This may be accounted for using electromagnetic modeling.

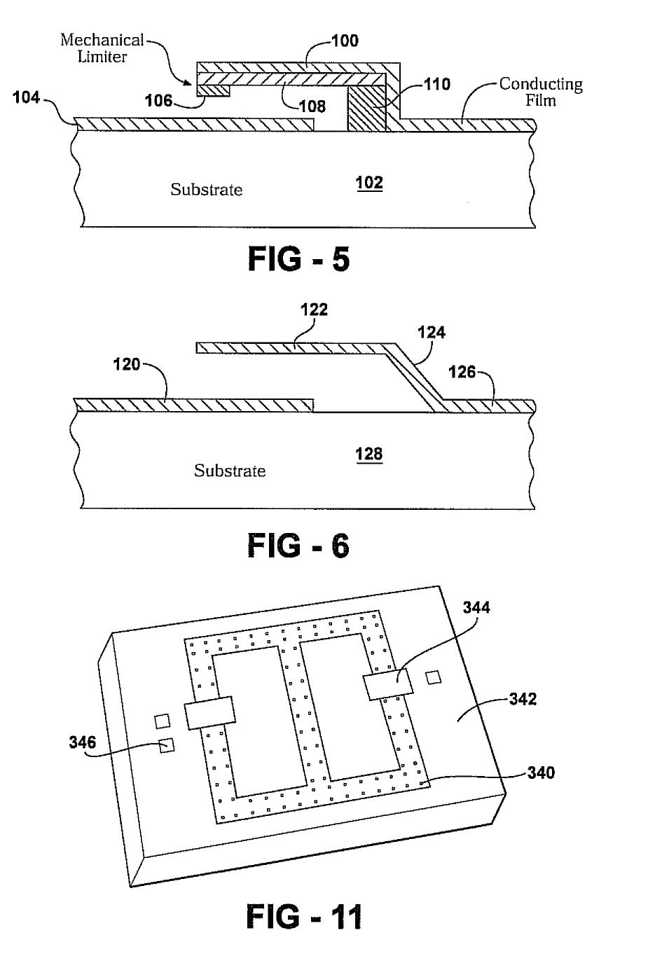

FIG. 5 shows in cross-section a first electrode 100 as part of an overleaf structure generally opposed to a second electrode 104 supported by substrate 102. This example illustrates mechanical limiting using insulating mechanical limiter 106. A mechanical limiter may also be positioned elsewhere, e.g. supported at the distal end of the first electrode 100, on the substrate, or otherwise located so as to help prevent direct electrical contact between electrodes 100 and 104. The mechanical limiting prevents short circuits between the first and second electrodes. The (optional) non-conducting overleaf support layer 108 is present on the underside of the first electrode, namely the side opposed to the substrate, and further prevents a short circuit. A support region 110 is used to support the overleaf structure so as to be spaced apart from the substrate.

FIG. 6 shows in cross-section a simplified schematic of a first electrode 122, as an extension of conducting segment 126, opposing a second electrode 120 supported by substrate 128. This figure illustrates that the support region 124 that supports the first electrode away from the substrate need not be orthogonal to the substrate as previously illustrated. In this example the support region is at an oblique angle to the substrate. An overleaf structure may be fabricated without an insulating support, for example using metal foil. The exact form of the overleaf structure may depend on the manufacturing technique used to fabricate the variable capacitor. In this example, the support region comprises a conducting film that electrically interconnects the first electrode and the elongated conducting element that is part of the conducting pattern. Other forms of support element may be other oblique angles, curved, or otherwise formed.

An electromagnetic beam control system according to some embodiments of the present invention comprise a metamaterial including a plurality of resonant circuits, the resonant circuits including a conducting pattern and a variable capacitor. A conducting pattern may be a split ring resonator, comprising at least one variable capacitor, the capacitance of which may be varied using a control signal applied through electrical connections. In some examples, a metamaterial may comprise a plurality of resonant circuits within a layer of the metamaterial. An apparatus may further comprise associated drive circuitry for applying control signals. An example metamaterial according to the present invention may include a plurality of tunable unit cells, so that application of a spatially varying bias voltage leads to a correlated spatial variation of index within the metamaterial.

A metamaterial lens may include one or more layers, for example a plurality of dielectric substrates each supporting an array of resonant circuits. A control circuit can be used to apply control signals to one or more of the layers, for example as a function of spatial position relative to a reference point, reference line, or reference plane. A radiation source may provide a radiation beam passing through a metamaterial lens, and the beam properties of the emerging beam can be adjusted using the control circuit. In this manner a beam control device can be provided, such as a refractive beam steering device.

In specific examples of the present invention, beam steering may be achieved using a variable control signal applied as a function of position across the metamaterial, so as to provide a variable index or gradient index lens. A gradient index lens may be used to modify the direction of the emergent beam, and the beam may be scanned in one or more planes. Such a configuration is useful for automotive applications, for example adaptive cruise control, parking assistance, hazard recognition systems, and the like.

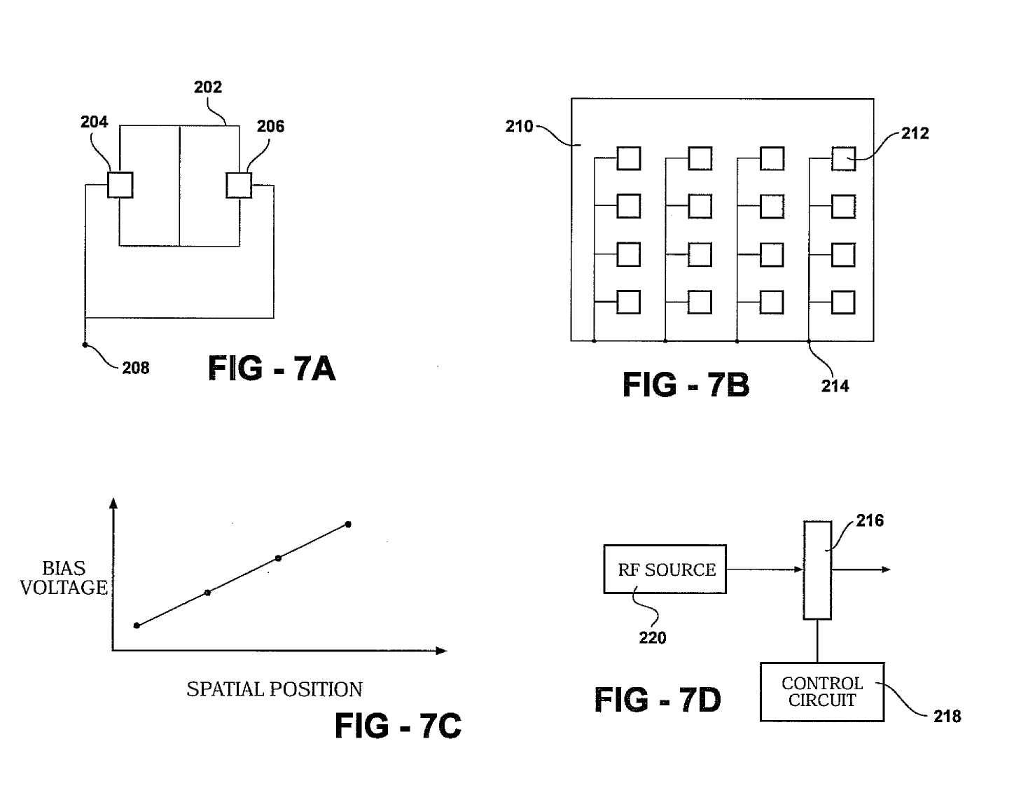

FIG. 7A-D illustrates aspects of an example electromagnetic control system according to some embodiments of the present invention.

FIG. 7A illustrates a conducting pattern, in this case a resonator, schematically at 202, comprising first and second tunable elements 204 and 206 respectively controlled using a control signal applied through control electrodes 208. One or both of the tunable elements may be adjustable capacitors, such as a variable capacitor as described herein. The resonator is one of a plurality of resonators present within a layer of the metamaterial.

FIG. 7B shows a substrate 210 including a plurality of conducting patterns, each conducting pattern being represented by a box such as 212. This may form a single layer of a metamaterial, and further comprises associated drive circuitry for applying bias voltages to tunable elements associated with each conducting pattern. Hence, an example metamaterial according to the present invention includes a plurality of tunable unit cells, so that, for example, application of a spatially varying bias voltage leads to a correlated spatial variation of index within the metamaterial. In this case, metamaterial index can be varied spatially by applying different potentials to each column of conducting patterns using electrodes 214.

FIG. 7C shows schematically how index may vary with bias voltage. The variation may be linear or non-linear with spatial dimension, along one or two axes, or otherwise varied.

FIG. 7D shows a metamaterial lens 216 including one or more layers such as 210, with a control circuit 218 used to apply control signals to one or more of the layers. A radiation source 220 provides radiation passing through the metamaterial lens, and the beam properties of the emerging beam can be adjusted using the control circuit. Hence, an improved beam steering device is provided.

In specific examples of the present invention, beam steering may be achieved using a variable bias voltage applied across the metamaterial, so as to provide a variable index or gradient index lens. A gradient index lens may be used to modify the direction of the emergent beam, for example through variable beam refraction, and the beam may be scanned in one or more planes. Such a configuration is useful for automotive applications, for example adaptive cruise control, parking assistance, hazard recognition systems, and the like.

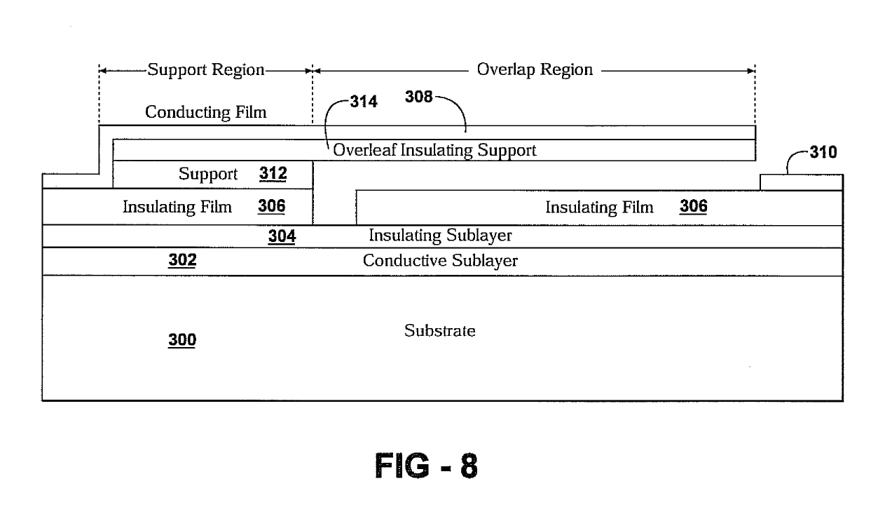

FIG. 8 shows a cross-section of part of an example structure, having a base substrate layer 300, conductive sub-layer 302, an insulating sub-layer 304, an insulating film 306, a first conducting film 308, a second conducting film 310, support region 312, and overleaf insulating support 314. The conducting film 312 and overleaf insulating support 314 provide a deformable overleaf structure. The conductive sublayer just above the substrate may be an undesirable source of loss and can be eliminated. In this example, the capacitance is between conductors 308 and 310, and the capacitance change due to actuation may be smaller than in other possible configurations. For example, in other examples the conducting film 310 may extend into the overlap region. In other examples, film 306 may be replaced by a conducting film, and in such examples the capacitance change can be made larger.

In one approach, deformation is achieved by applying a potential between first and second conducting films. In other approaches, a potential is applied between an electrode supported by the overleaf insulating support and an electrode supported by the substrate, one or both of these deformation control electrodes being electrically isolated from the conducting pattern that forms the resonant structure. In some examples, two or more such pairs of deformation control electrodes may be used, for example a pair of such electrodes each side of a conducting segment of the resonant circuit.

In a representative example, a capacitor was made with an approximately 100 micron overlap region and a 1.5 micron support region. The substrate base layer was insulating silicon and approximately 500 microns thick, the conductive sub-layer comprise conductive silicon with a film thickness of 0.5 microns, the insulating sub-layer was silicon nitride with a film thickness of 0.6 microns, a conducting polysilicon film 306 with a film thickness of 2 microns, with an additional support layer thickness of 1.5 microns, the conducting film 308 comprised gold of 0.5 microns thickness, and the overleaf insulating support comprised conducting polysilicon with a thickness of 0.5 microns. The vertical and horizontal spatial separation of polysilicon structures in the overleaf region was 2 microns. In other examples, the conducting film thickness was reduced to 40 nanometers in the overlap region. However these example dimensions are exemplary and are not limiting on the present invention.

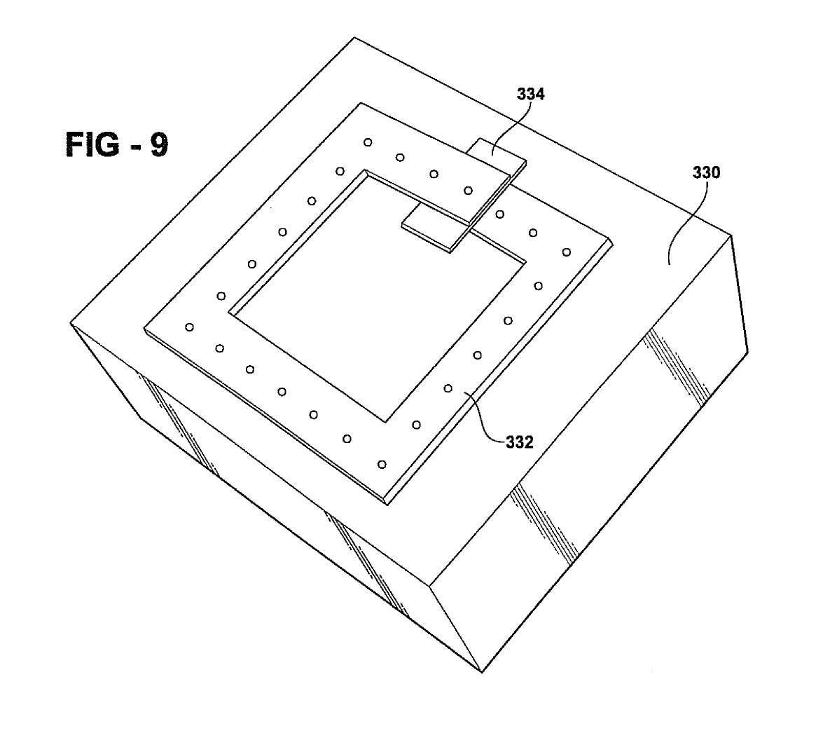

FIG. 9 shows a representation of a unit cell having a split ling resonator including a variable capacitor. For example a variable capacitor may have the cross-section as shown in FIG. 8, and optionally a configuration such as discussed in relation to FIG. 4B. In this example, the split ring resonator 332 is a single ring supported on substrate 330, and the variable capacitor 334 is located within the capacitive gap.

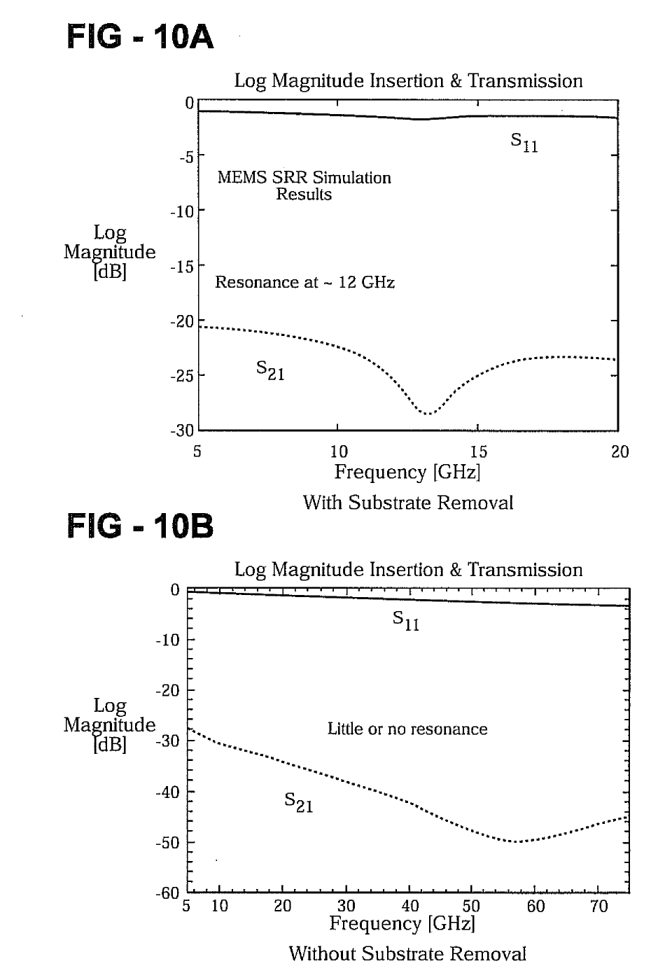

FIGS. 10A-B show electromagnetic responses simulated for a metamaterial having a unit cell structure such as shown in FIG. 9 and variable capacitor such as discussed in relation to FIG. 8. The simulation results indicate a more pronounced resonance with the substrate removed, presumably due to losses in the substrate material, silicon in this simulation. The substrate material may be chosen to achieve a desired resonant frequency, resonance width, and/or other electromagnetic parameter. Glass and sapphire substrates, when simulated in a similar configuration, gave a response closer to air or the “substrate removed” case.

The permittivity of the substrate (e.g. different substrate compositions), conductive pattern conductivity (e.g. metal film composition and thickness), and other parameters may be varied to adjust resonance properties.

FIG. 11 shows a schematic of a unit cell including a resonator having two variable capacitors formed within gaps of a conducting pattern. The figure shows a conducting pattern 340 in a resonator form having two capacitive gaps. A variable capacitor, such as 344, is located in each of the capacitive gaps. Conducting pads 346 allow electrical connection to be made to the variable capacitor through tracks on the substrate (not shown).

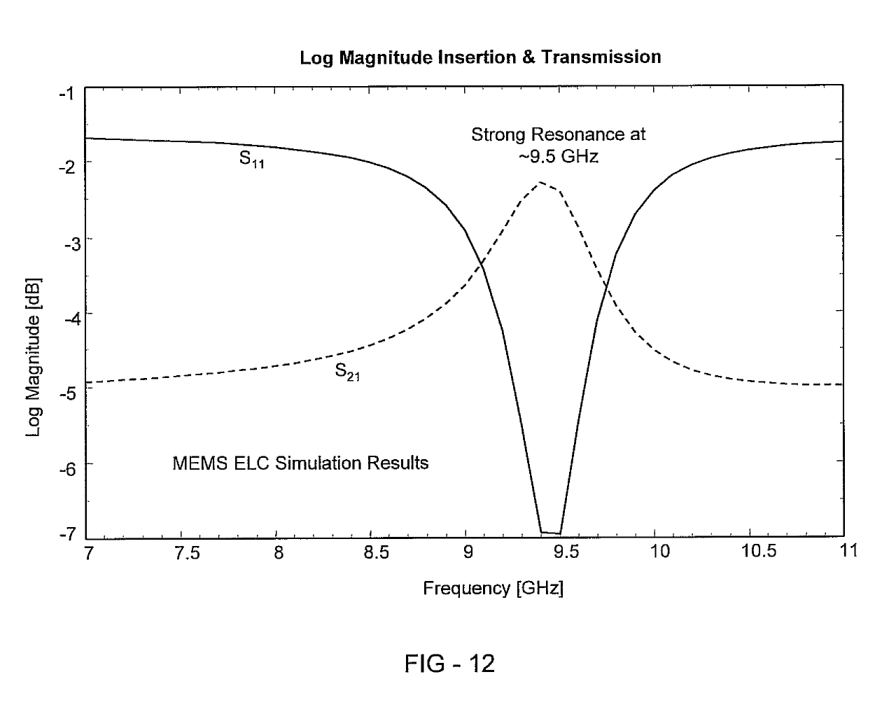

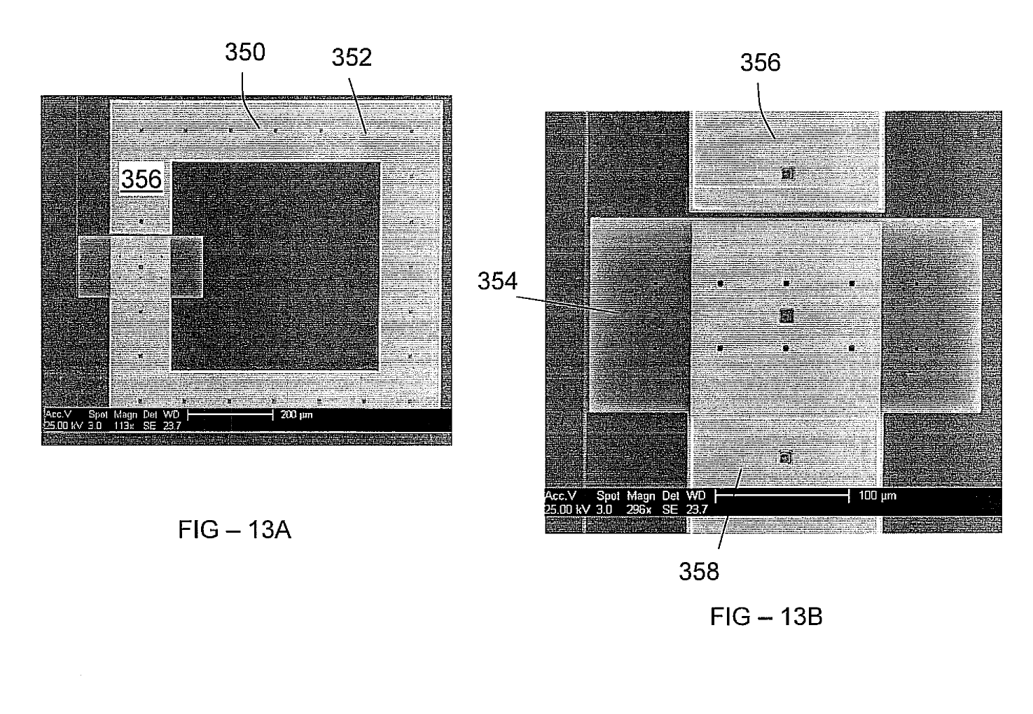

FIG. 12 shows simulation results for a metamaterial having a unit cell structure such as shown in FIG. 11, indicating a strong resonance at approximately 9.5 gigahertz. The simulation shows parameters S₁₁ and S₂₁, indicating a strong resonance at approximately 9.5 GHz.

Tuning of a resonance through deformation of the overlapping structure can be used to modify the resonance frequency, and hence modify the index at the operating frequency of the metamaterial. The operating frequency may be within typical designated public operating frequencies for radar or similar resonator devices.

A particular example application is controlled beam steering for radar applications, for example, a metamaterial according to the present invention may be used in an automotive radar. The operating frequency may be approximately 77 gigahertz or have a wide bandwidth about 79 gigahertz, or other suitable frequency. In such an application, the resonant frequency of any particular resonator may be selected to be somewhat less than the operational frequency, for example in the range of 40 to 70 gigahertz, so that the metamaterial acts as a positive index material at the operating frequency. In some examples, an operating frequency may be approximately ≦0.8 or ≧1.2 times the resonant frequency. Micro-fabrication techniques may be used for fabrication of such metamaterials.

FIGS. 13A-B show electron microscope images of a tunable resonant circuit. FIG. 13A shows a resonator 350 with a capacitive gap on the middle left, shown in more detail in FIG. 13B. The variable capacitor is located between a first conducting segment 356 and a second conducting segment 358. The holes 352 facilitate etching steps, and are also represented in FIGS. 9 and 11. A high selectivity gas etch was used to etch silicon, for substrate removal directly underneath a split ring resonator. Photoresist was used to protect the polysilicon MEMS structures. The overleaf structure is shown at 354, and deformation control electrodes can be positioned underneath (as imaged here) this structure so as to be not visible in this view.

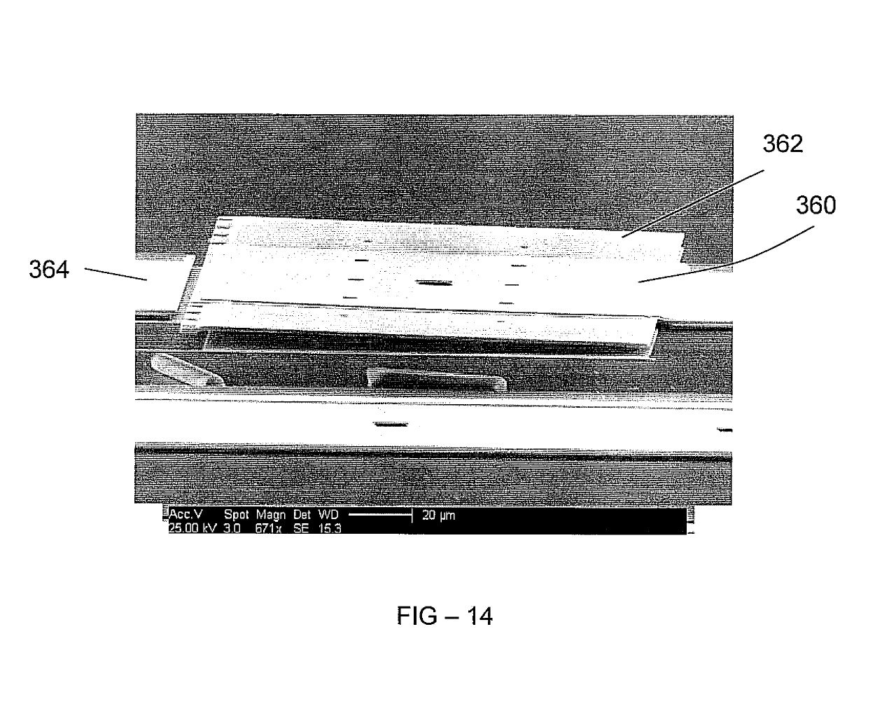

FIG. 14 shows an electron microscope image of a variable capacitor, similar to that shown in FIG. 13, from an oblique aspect. The figure shows a first conducting segment 360 extending over deformable overleaf structure 362. A capacitive gap, having variable capacitance, is formed with the end of second conducting segment 364. The conducting segments may correspond to segments 356 and 358 in FIG. 13B, but other conducting patterns may be used. Deformation control electrodes can be supported by the substrate, underneath the deformable overleaf structure.

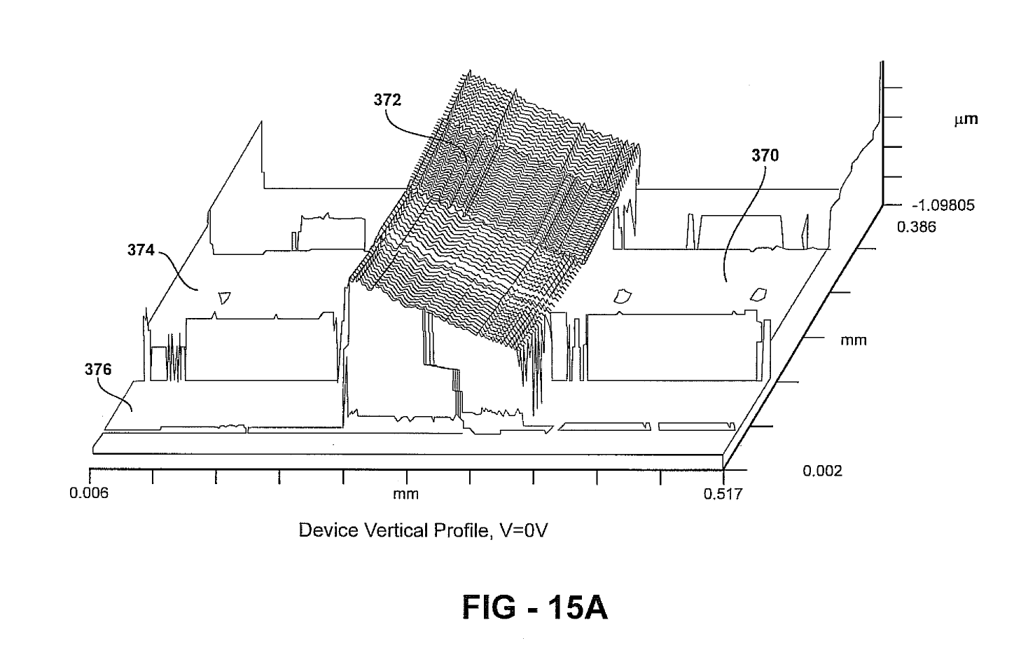

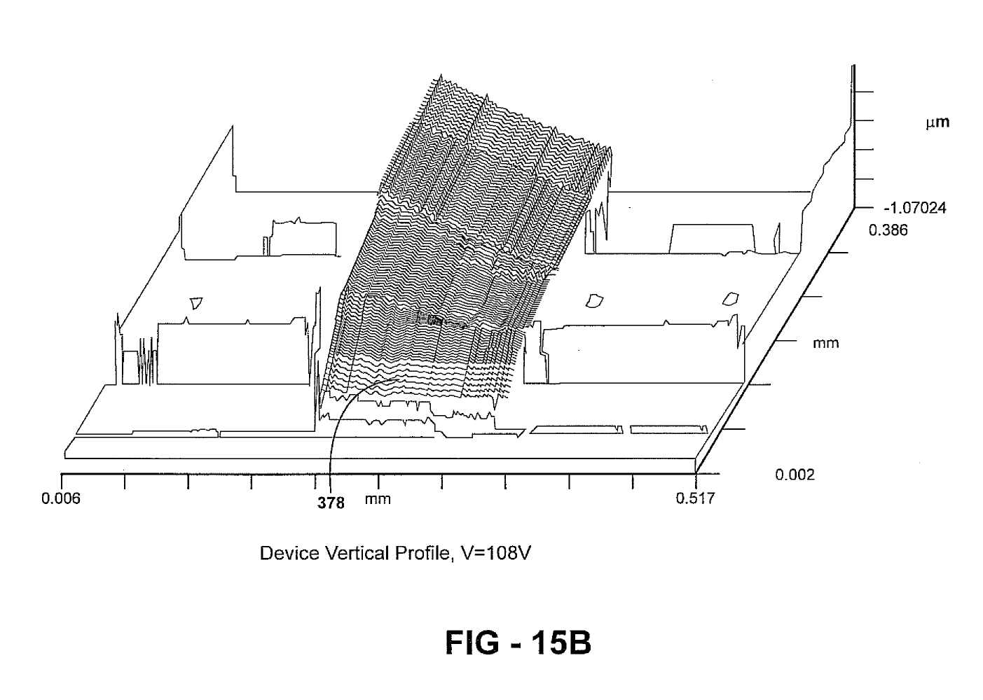

FIGS. 15A-B show optical micrographs of variable capacitor operation, the overleaf structure being deformed by an electrical field. FIG. 15A shows the device profile with no potential applied. First and second conducting segments 370 and 374 are supported on substrate 376. First conducting segment is extended at 372 onto a deformable structure. FIG. 15B shows partial deformation with 108V applied, with part of the deformable structure 378 being pulled down towards the substrate.

In this example, the capacitor top plate was stressed by the metal layer, which decreased capacitance and presumably increased the resonance frequency. Actuation voltages were designed to be ˜10V, but actual observations were higher. Temperature can be used to compensate for capacitor stress, and a low stress metal can be used to reduce or eliminate these effects.

Embodiments of the present invention include a metamaterial having a deformable structure that is deformable by a control voltage applied between a pair of conducting regions. These conducting regions may be the first and second electrodes of the variable capacitor, though this is not necessary. The first conducting region may be supported by a substrate and the second conducting region supported by the deformable structure. The deformable structure may be deformable by a control voltage applied between the first and second conducting regions. The control voltage may be varied in a manner correlated with a spatial position variable of the resonant circuit so as to obtain a gradient index lens. An electrical control signal can induce a voltage-controllable electrode separation through a deformation of an electrode of the variable capacitor relative to the other electrode.

The invention is not restricted to the illustrative examples described above. Examples are not intended as limitations on the scope of the invention. Methods, apparatus, compositions, and the like described herein are exemplary and not intended as limitations on the scope of the invention. Changes therein and other uses will occur to those skilled in the art. The scope of the invention is defined by the scope of the claims.

Having described our invention, we claim:

1. A metamaterial, the metamaterial comprising a plurality of resonant circuits, at least one resonant circuit being a tunable resonant circuit including a variable capacitor having a deformable electrode, the deformable electrode being deformable by an electrical control signal so as to modify electromagnetic properties of the resonant circuit.

2. The metamaterial of claim 1, the metamaterial comprising a plurality of tunable resonant circuits.

3. The metamaterial of claim 1, the tunable resonant circuit including a conducting pattern having a capacitive gap,
the variable capacitor being located proximate to the capacitive gap.

4. The metamaterial of claim 3, the variable capacitor being located within the capacitive gap.

5. The metamaterial of claim 3, the resonant circuit being a split ring resonator.

6. The metamaterial of claim 1, the plurality of resonant circuits being supported by a substrate.

7. The metamaterial of claim 6, the variable capacitor including a first electrode supported by the substrate, the deformable electrode being spaced apart from the first electrode by a support structure.

8. A metamaterial, the metamaterial being an artificially patterned composite material comprising:
a substrate;
a plurality of conducting patterns supported by the substrate, each conducting pattern being associated with a variable capacitor,
each variable capacitor having an electrode separation controllable using an electrical control signal.

9. The metamaterial of claim 8, each variable capacitor having a first electrode supported by the substrate and a second electrode,
the second electrode being deformable relative to the first electrode using the electrical control signal.

10. A metamaterial, the metamaterial being an artificially patterned composite material comprising:
a substrate;
a plurality of resonator circuits supported by the substrate, each resonator circuit comprising a conducting pattern and a variable capacitor,
each variable capacitor having a first electrode and a second electrode,
the first electrode being supported by the substrate, and
the second electrode being supported by a deformable structure spaced apart from the substrate,
the deformable structure being deformable using a control voltage so as to modify the capacitance of the variable capacitor.

11. The metamaterial of claim 10, the deformable structure being deformable by a control voltage applied between the first and second electrodes.

12. The metamaterial of claim 10, the deformable structure being deformable by a control voltage applied between the a first conducting region and a second conducting region,
the first conducting region being supported by the substrate,
the second conducting region being supported by the deformable structure.

13. The metamaterial of claim 12, the first conducting region being electrically isolated from the first electrode.

14. The metamaterial of claim 12, the second conducting region being electrically isolated from the second electrode.

15. The metamaterial of claim 10, the substrate being a substantially planar dielectric substrate.

16. The metamaterial of claim 15, the metamaterial comprising a plurality of substantially parallel substrates.

17. The metamaterial of claim 10, further comprising an electronic control circuit,
the electronic control circuit being operable to induce a gradient index over the metamaterial.
